(19) United States
(12) Patent Application Publication
(10) Pub. No.: US 2007/0181973 A1
(43) Pub. Date: Aug. 9, 2007

(54) CAPACITOR STRUCTURE

(76) Inventors: Cheng-Chou Hung, Hsinchu County (TW); Victor Liang, Hsinchu City (TW); Hua-Chou Tseng, Hsinchu (TW); Chih-Yu Tseng, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,396

(22) Filed: Feb. 6, 2006

(51) Int. Cl. H01L 29/00

(52) U.S. Cl. 257/532

(57) ABSTRACT

A capacitor structure including a plurality of conductive layers, a dielectric layer and a plurality of contacts is disclosed. The conductive layers are stacked, and each conductive layer has a first conductive pattern and a second conductive pattern. The dielectric layer is disposed between the first conductive pattern and the second conductive pattern and between two adjacent conductive layers. The contacts are disposed in the dielectric layer, and electrically connected to the first conductive patterns in two adjacent conductive layers and electrically connected to the second conductive patterns in two adjacent conductive layers. Wherein, the contact electrically connecting to the first conductive patterns in two adjacent conducive layers is a first strip contact, which extends between the first conductive patterns in two adjacent conductive layers, and the boundary of the first strip contact is located within the boundary of the first conductive pattern.

### BACKGROUND OF THE INVENTION

1. Field of Invention

The present invention relates to a capacitor structure. More particularly, the present invention relates to a capacitor structure having high unit area capacitance.

2. Description of Related Art

Capacitor is one of the indispensable elements in an integrated circuit. During the design and fabricating process of a capacitor, the capacitance and allocation area of the capacitor have to be considered, thus a better design and fabricating process for capacitor can be provided.

Generally speaking, capacitors can be divided into 3 categories: metal-insulator-meta (MIM) capacitor, metal-line to metal-line (MOM) capacitor, and metal-insulator-silicon (MIS) capacitor. Wherein, the MIM capacitor and the MOM capacitor are widely used in deep sub-micron ICs, however, the unit area capacitance thereof is low. In addition, if the material with high dielectric constant is used, even though high capacitance density can be achieved, the problems of complicated fabricating process and high manufacturing cost still exist. Moreover, the reliability of the capacitor is low.

Along with the increase of integration and the decrease of semiconductor device size, the space for capacitors is getting smaller and smaller, thus, the capacitance of the capacitor is also reduced. In addition, in the deep sub-micron process, the problem of the reduction of capacitance becomes even more serious.

Thus, how to provide a capacitor structure with high integration and high capacitance in the present IC fabricating process, and how to effectively increase the surface area of the electrode to improve the performance of the capacitor while the space for storing the capacitor is getting smaller are presently the major subjects in IC design.

### SUMMARY OF THE INVENTION

Accordingly, the present invention is directed to provide a capacitor structure with high unit area capacitance.

According to another aspect of the present invention, a capacitor structure is provided which can prevent bridge effect between various conductive materials in the capacitor.

According to yet another aspect of the present invention, a capacitor structure having good compatibility is provided.

According to a further aspect of the present invention, a capacitor structure for increasing the capacitance of a capacitor is provided.

The present invention provides a capacitor structure including a plurality of conductive layers, a dielectric layer and a plurality of contacts. The conductive layers are stacked, and each conductive layer has a first conductive pattern and a second conductive pattern. The dielectric layer is disposed between the first conductive pattern and the second conductive pattern and between two adjacent conductive layers. The contacts are disposed in the dielectric layer, and electrically connected to the first conductive patterns in two adjacent conductive layers and to the second conductive patterns in two adjacent conductive layers, respectively. Wherein, the contact electrically connecting to the first conductive patterns in two adjacent conductive layers is a first strip contact, which extends between the first conductive patterns in two adjacent conductive layers, and the boundary of the first strip contact is located within the boundary of the first conductive pattern.

According to an exemplary embodiment of the present invention, in the foregoing capacitor structure, the contact electrically connecting to the second conductive patterns in two adjacent conductive layers includes a second strip contact, which extends between the second conductive patterns in two adjacent conductive layers, and the boundary of the second strip contact is located within the boundary of the second conductive pattern.

According to an exemplary embodiment of the present invention, in the foregoing capacitor structure, the contact electrically connecting to the second conductive patterns in two adjacent conductive layers includes a column contact.

According to an exemplary embodiment of the present invention, in the foregoing capacitor structure, the material of the conductive layers includes metal.

According to an exemplary embodiment of the present invention, in the foregoing capacitor structure, the material of the contacts includes metal.

The present invention further provides a capacitor structure including a plurality of conductive layers, a dielectric layer and a plurality of contacts. The conductive layers are stacked, each conductive layer has a first comb conductive pattern and a second comb conductive patter, and the teeth of each first comb conductive pattern and the teeth of each second comb conductive pattern are disposed interlacedly. The dielectric layer is disposed between the first comb conductive pattern and the second comb conductive pattern and between two adjacent conductive layers. The contacts are disposed in the dielectric layer and electrically connected to the first comb conductive patterns in two adjacent conductive layers and to the second comb conductive patterns in two adjacent conductive layers respectively. Wherein, the contact electrically connecting to the first comb conductive patterns in two adjacent conductive layers is a first comb contact; the pattern of the first comb contact corresponds to the pattern of the first comb conductive pattern; and the boundary of the first comb contact is located within the boundary of the first comb conductive pattern.

According to an exemplary embodiment of the present invention, in the foregoing capacitor structure, the contact electrically connecting to the second comb conductive patterns in two adjacent conductive layers includes a second comb contact; the pattern of the second comb contact corresponds to the pattern of the second comb conductive pattern; and the boundary of the second comb contact is located within the boundary of the second comb conductive pattern.

According to an exemplary embodiment of the present invention, in the foregoing capacitor structure, the contact electrically connecting to the second comb conductive patterns in two adjacent conductive layers includes a column contact.

The present invention further provides a capacitor structure including a plurality of conductive layers, a dielectric layer and a plurality of contacts. The conductive layers are stacked, and each conductive layer has a first spiral conductive pattern and a second spiral conductive pattern disposed interlacedly. The dielectric layer is disposed between the first spiral conductive pattern and the second spiral conductive pattern and between two adjacent conductive layers. The contacts are disposed in the dielectric layer and electrically connected to the first spiral conductive patterns in two adjacent conductive layers and to the second spiral conductive patterns in two adjacent conductive layers, respectively. Wherein, the contact electrically connecting to the first spiral conductive patterns in two adjacent conductive layers is a first spiral contact; the pattern of the first spiral contact corresponds to the pattern of the first spiral conductive pattern; and the boundary of the first spiral contact is located within the boundary of the first conductive pattern.

According to an exemplary embodiment of the present invention, in the foregoing capacitor structure, the contact electrically connecting to the second spiral conductive patterns in two adjacent conductive layers includes a second spiral contact; the pattern of the second spiral contact corresponds to the pattern of the second spiral conductive pattern; and the boundary of the second spiral contact is located within the boundary of the second spiral conductive pattern.

According to an exemplary embodiment of the present invention, in the foregoing capacitor structure, the contact electrically connecting to the second spiral conductive patterns in two adjacent conductive layers includes a column contact.

The present invention further provides a capacitor structure including a plurality of conductive layers, a dielectric layer and a plurality of contacts. The conductive layers are stacked; each conductive layer has a first conductive pattern and a second conductive pattern; the first conductive pattern has an opening and the second conductive pattern is disposed in the opening. The dielectric layer is disposed between the first conductive pattern and the second conductive pattern and between two adjacent conductive layers. The contacts are disposed in the dielectric layer and electrically connected to the first conductive patterns in two adjacent conductive layers and to the second conductive patterns in two adjacent conductive layers, respectively. Wherein, the contact electrically connecting to the first conductive patterns in two adjacent conductive layers is a circular contact; the pattern of the circular contact corresponds to the pattern of the first conductive pattern; and the boundary of the circular contact is located within the boundary of the first conductive pattern.

According to an exemplary embodiment of the present invention, in the foregoing capacitor structure, the contact electrically connecting to the second conductive patterns in two adjacent conductive layers includes a strip contact, which extends between the second conductive patterns in two adjacent conductive layers, and the boundary of the strip contact is located within the boundary of the second conductive pattern.

According to an exemplary embodiment of the present invention, in the foregoing capacitor structure, the contact electrically connecting to the second conductive patterns in two adjacent conductive layers includes a column contact.

In the capacitor structure of the present invention, since the contact used for connecting to two adjacent conductive layers is a strip contact, which extends between the second conductive patterns in two adjacent conductive layers, or is a contact having a pattern corresponding to the conductive patterns in the conductive layers, the unit area capacitance can be improved. In addition, the boundary of the strip contact or the boundary of the contact having the pattern corresponding to the conductive patterns in the conductive layers is located within the boundary of the conductive pattern in two adjacent conductive layers, so that the bridge effect between various conductive materials in the capacitor can be avoided, and the compatibility of the capacitor is good. On the other hand, by disposing the contacts, the capacitor in the present invention can be formed by more than two conductive layers, thus the unit area capacitance of the capacitor can be further increased.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a capacitor structure according to an embodiment of the present invention.

FIG. 2 is a profile view of the capacitor structure cut along line A-A′ in FIG. 1.

FIG. 3 is a top view of a capacitor structure according to another embodiment of the present invention.

FIG. 4 is a top view of a comb capacitor structure according to an embodiment of the present invention.

FIG. 5 is a top view of a comb capacitor structure according to another embodiment of the present invention.

FIG. 6 is a top view of a spiral capacitor structure according to an embodiment of the present invention.

FIG. 7 is a top view of a spiral capacitor structure according to another embodiment of the present invention.

FIG. 8 is a top view of a capacitor structure according to yet another embodiment of the present invention.

FIG. 9 is a top view of a capacitor structure according to yet another embodiment of the present invention.

FIG. 10 is a perspective view of FIG. 8.

FIG. 11 is a perspective view of FIG. 9.

### DESCRIPTION OF EMBODIMENTS

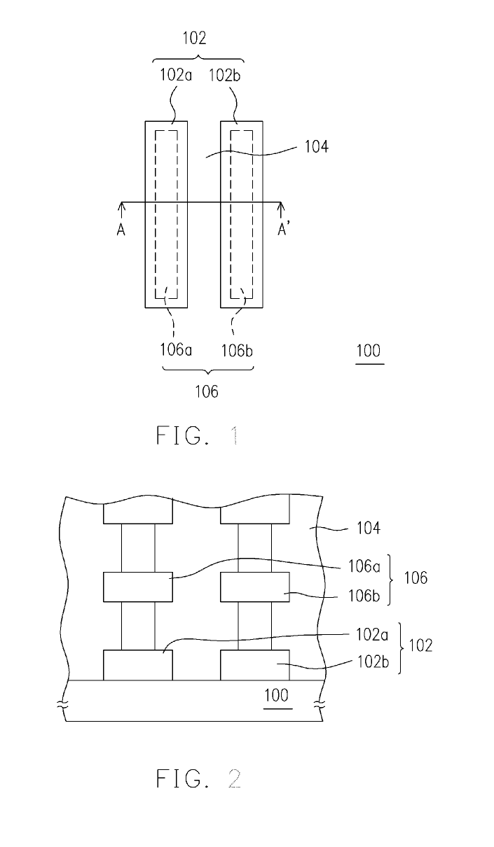

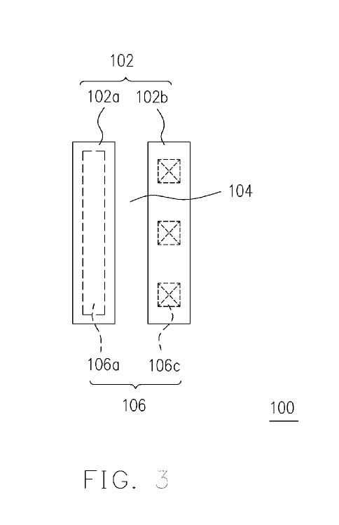

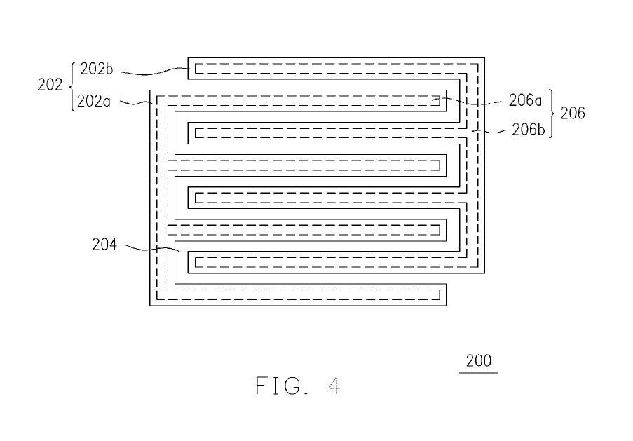

FIG. 1 is a top view of a capacitor structure according to an embodiment of the present invention. FIG. 2 is a profile view of the capacitor structure cut along line A-A′ in FIG. 1. FIG. 3 is a top view of a capacitor structure according to another embodiment of the present invention.

First, referring to FIG. 1 and FIG. 2, the capacitor structure includes a plurality of conductive layers 102, a dielectric layer 104, and a plurality of contacts 106 disposed on a substrate 100. The substrate 100 is, for example, a silicon substrate.

The conductive layers 102 are stacked, and each conductive layer 102 has a conductive pattern 102a and a conductive pattern 102b. The material of the conductive layers 102 is conductive material such as metal. Here, the plurality of the conductive layers 102 means that at least 2 layers are included. For those of ordinary skill in the art, the number of the conductive layers 102 can be adjusted according to the requirement in IC design.

The dielectric layer 104 is disposed between the conductive pattern 102a and the conductive pattern 102b and between two adjacent conductive layers 102. The material of the dielectric layer 104 is dielectric material such as silicon oxide or silicon nitride.

The contacts 106 are disposed in the dielectric layer 104 and electrically connected to the conductive patterns 102a in two adjacent conductive layers 102 and to the conductive patterns 102b in two adjacent conductive layers 102, respectively. The material of the contacts 106 is suitable material such as metal. Wherein, the contact 106 electrically connecting to the conductive patterns 102a in two adjacent conductive layers 102 is, e.g. a strip contact 106a which extends between the conductive patterns 102a in two adjacent conductive layers 102, and the boundary of the strip contact 106a is located within the boundary of the conductive pattern 102a.

In addition, the contact 106 electrically connecting to the conductive patterns 102b in two adjacent conductive layers 102 is, e.g. a strip contact 106b, which extends between the conductive patterns 102b in two adjacent conductive layers 102, and the boundary of the strip contact 106b is located within the boundary of the conductive pattern 102b.

Next, referring to FIG. 3, in another embodiment, the contact 106 electrically connecting to the conductive patterns 102b in two adjacent conductive layers 102 is, e.g. a column contact 106c.

Because the contacts 106 used for connecting two adjacent conductive layers 102 are strip contacts 106a and 106b, and which extend between the conductive patterns 102a and 102b in two adjacent conductive layers 102 respectively, the surface area of the capacitor is increased; accordingly, the unit area capacitance can be improved. In addition, the boundaries of the strip contacts 106a and 106b are respectively located within the boundaries of the conductive patterns 102a and 1026 in two adjacent conductive layers 102, thus the bridge effect between various conductive materials during the fabricating process of the capacitor can be avoided, and the compatibility of the capacitor is good. Moreover, by disposing the contacts 106, the capacitor in the present invention can be formed by more than two conductive layers 102, thus the unit area capacitance of the capacitor can be further improved.

Below, various types of capacitor structures in the present invention will be explained with reference to embodiments.

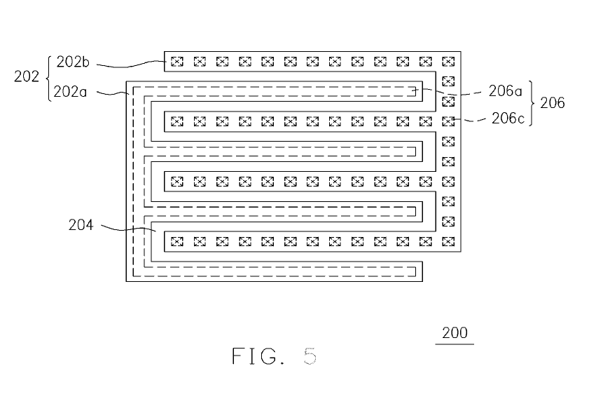

FIG. 4 is a top view of a comb capacitor structure according to an embodiment of the present invention. FIG. 5 is a top view of a comb capacitor structure according to another embodiment of the present invention.

First, referring to FIG. 4 first, the capacitor structure has a plurality of conductive layers 202, a dielectric layer 204, and a plurality of contacts 206 disposed on a substrate 200. The substrate 200 is, e.g. a silicon substrate.

The conductive layers 202 are stacked; each conductive layer 202 has a comb conductive pattern 202a and a comb conductive pattern 202b; and the teeth of the comb conductive pattern 202a and the teeth of the comb conductive pattern 202b are disposed interlacedly. The material of the conductive layers 202 is conductive material such as metal. Here, the plurality of conductive layers 202 means at least 2 layers are included. For those of ordinary skill in the art, the number of the conductive layers 202 can be adjusted according to the requirement in IC design.

The dielectric layer 204 is disposed between the comb conductive pattern 202a and the comb conductive pattern 202b and between two adjacent conductive layers 202. The material of the dielectric layer 204 is dielectric material such as silicon oxide or silicon nitride.

The contacts 206 are disposed in the dielectric layer 204 and electrically connected to the comb conductive patterns 202a in two adjacent conductive layers 202 and electrically connected to the comb conductive patterns 202b in two adjacent conductive layers 202, respectively. The material of the contacts 206 is suitable material such as metal. Wherein, the contact 206 electrically connecting to the comb conductive patterns 202a in two adjacent conductive layers 202 is, e.g. a comb contact 206a; the pattern of the comb contact 206a corresponds to the pattern of the comb conductive pattern 202a; and the boundary of the comb contact 206a is located within the boundary of the comb conductive pattern 202a.

In addition, the contact 206 electrically connecting to the comb conductive patterns 202b in two adjacent conductive layers 202 is, e.g. a comb contact 206b; the pattern of the comb contact 206b corresponds to the pattern of the comb conductive pattern 202b; and the boundary of the comb contact 206b is located within the boundary of the comb conductive pattern 202b.

Next, referring to FIG. 5, in another embodiment, the contact 206 electrically to connecting the comb conductive patterns 202b in two adjacent conductive layers 202 is, e.g. a column contact 206c.

According to the present invention, since the two conductive patterns served as electrodes are disposed correspondingly in the form of combs to increase the unit area wire length of a particular electrode on the same conductive layer, thus the unit area capacitance of the capacitor is improved.

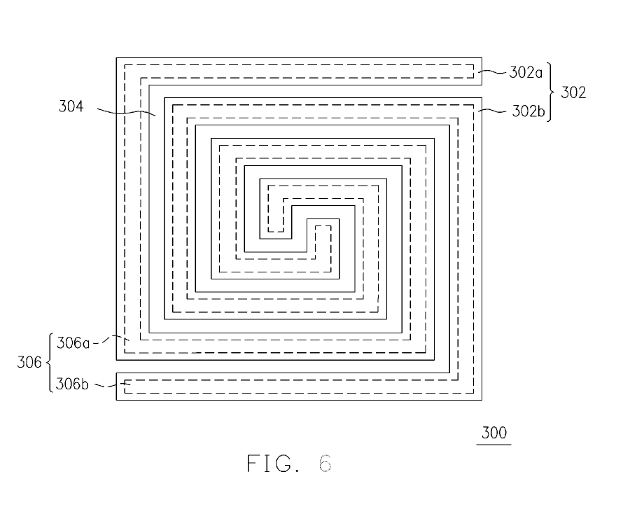

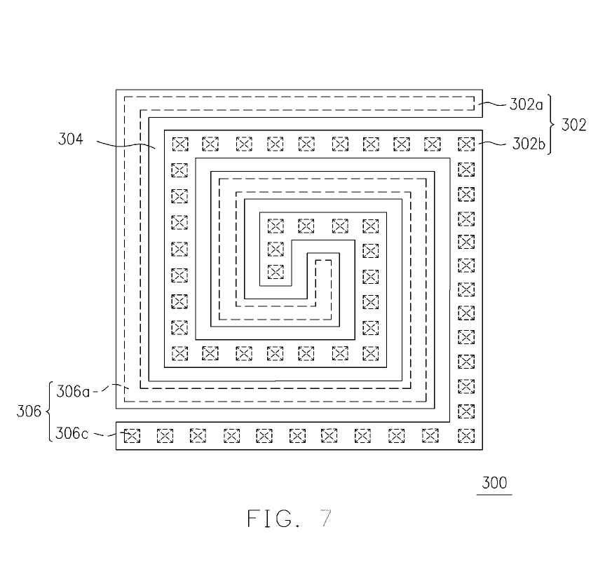

FIG. 6 is a top view of a spiral capacitor structure according to an embodiment of the present invention. FIG. 7 is a top view of a spiral capacitor structure according to another embodiment of the present invention.

First, referring to FIG. 6, the capacitor structure has a plurality of conductive layers 302, a dielectric layer 304 and a plurality of contacts 306 disposed on a substrate 300. The substrate 300 is, e.g. a silicon substrate.

The conductive layers 302 are stacked, and each conductive layer 302 has a spiral conductive pattern 302a and a spiral conductive pattern 302b disposed interlacedly. The material of the conductive layers 302 is conductive material such as metal. Here, the plurality of the conductive layers 302 means that at least 2 layers are included. For those of ordinary skill in the art, the number of the conductive layers 302 can be adjusted according to the requirement in IC design. In addition, the spiral conductive patterns 302a and 302b can be other spiral patterns, such as arc, oval, triangle, polygon, or trapezoid, besides the rectangle spiral pattern shown in FIG. 6 or other types of rectangle spiral patterns.

The dielectric layer 304 is disposed between the spiral conductive patterns 302a and 302b and between two adjacent conductive layers 302. The material of the dielectric layer 304 is dielectric material such as silicon oxide or silicon nitride.

The contacts 306 are disposed in the dielectric layer 304 and electrically connected to the spiral conductive patterns 302a in two adjacent conductive layers 302 and to the spiral conductive patterns 302b in two adjacent conductive layers 302, respectively. The material of the contacts 306 is suitable material such as metal. Wherein, the contacts 306 electrically connecting to the spiral conductive patterns 302a in two adjacent conductive layers 302 is, e.g. a spiral contact 306a; the pattern of the spiral contact 306a corresponds to the pattern of the spiral conductive pattern 302a; and the boundary of the spiral contact 306a is located within the boundary of the spiral conductive pattern 302a.

In addition, the contact 306 electrically connecting to the spiral conductive patterns 302b in two adjacent conductive layers 302 is, e.g. a spiral contact 306b; the pattern of the spiral contact 306b corresponds to the pattern of the spiral conductive pattern 302b; and the boundary of the spiral contact 306b is located within the boundary of the spiral conductive pattern 302b.

Next, referring to FIG. 7, in another embodiment, the contact 306 electrically connecting to the spiral conductive patterns 302b in two adjacent conductive layers 302 is, e.g. a column contact 306c.

According to the present invention, because the two conductive patterns served as electrodes are disposed correspondingly in a spiral form to increase the unit area wire length of a particular electrode on the same conductive layer, the unit area capacitance of the capacitor is improved.

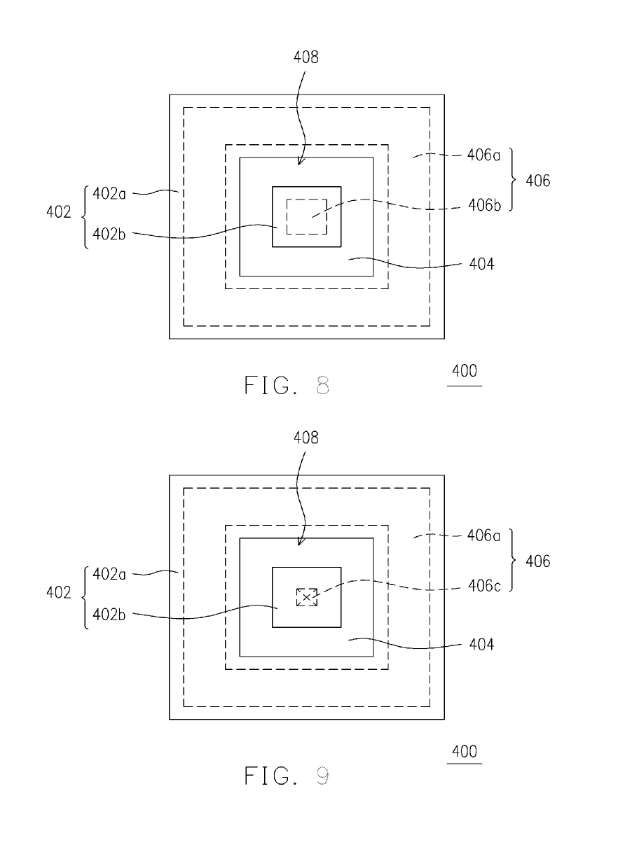

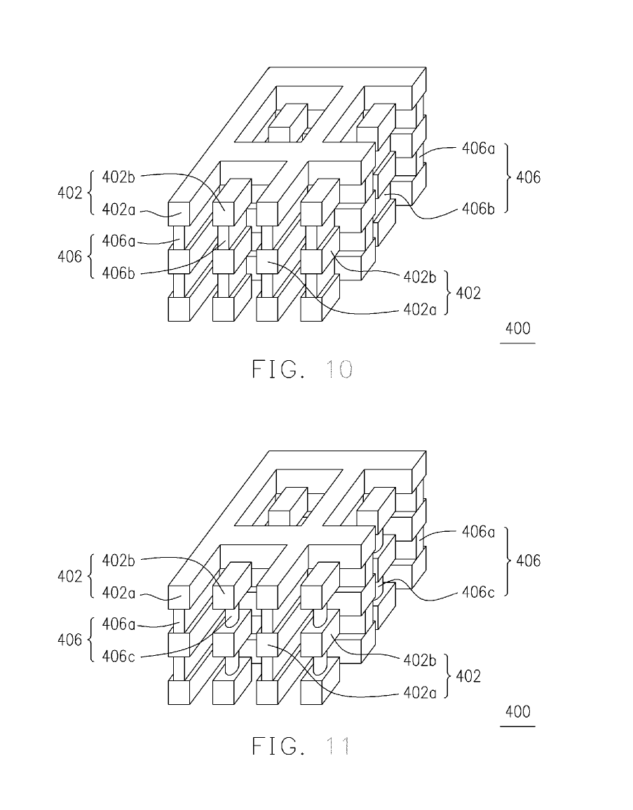

FIG. 8 is a top view of a capacitor structure according to yet another embodiment of the present invention. FIG. 9 is a top view of a capacitor structure according to yet another embodiment of the present invention. FIG. 10 is a perspective view of FIG. 8. FIG. 11 is a perspective view of FIG. 9.

First, referring to FIG. 8, the capacitor structure has a plurality of conductive layers 402, a dielectric layer 404 and a plurality of contacts 406 disposed on a substrate 400. The substrate 400 is, e.g. a silicon substrate.

The conductive layers 402 are stacked; each conductive layer 402 has a conductive pattern 402a and a conductive pattern 402b; the conductive pattern 402a has an opening 408 and the conductive pattern 402b is disposed in the opening 408. The material of the conductive layers 402 is conductive material such as metal. Here, the plurality of conductive layers 402 means at least 2 layers are included. For those of ordinary skill in the art, the number of the conductive layers 402 can be adjusted according to the requirement in IC design.

The dielectric layer 404 is disposed between the conductive pattern 402a and the conductive pattern 402b and between two adjacent conductive layers 402. The material of the dielectric layer 404 is dielectric material such as silicon oxide or silicon nitride.

The contacts 406 are disposed in the dielectric layer 404 and electrically connected to the conductive patterns 402a in two adjacent conductive layers 402 and to the conductive patterns 402b in two adjacent conductive layers 402, respectively. The material of the contacts 406 is suitable material such as metal. Wherein, the contact 406 electrically connecting to the conductive patterns 402a in two adjacent conductive layers 402 is, e.g. a circular contact 406a; the pattern of the circular contact 406a corresponds to the pattern of the conductive pattern 402a; and the boundary of the circular contact 406a is located within the boundary of the conductive pattern 402a.

In addition, the contact 406 electrically connecting to the conductive patterns 402b in two adjacent conductive layers 402 is, e.g. a strip contact 406b, which extends between the conductive patterns 402b in two adjacent conductive layers 402, and the boundary of the strip contact 406b is located within the boundary of the conductive pattern 402b.

Next, referring to FIG. 9, in the another embodiment, the contact electrically connecting to the conductive patterns 402b in two adjacent conductive layers 402 is, e.g. a column contact 406c.

In addition, it is remarkable that even though the conductive pattern 402a shown in FIG. 8 and FIG. 9 has only one opening 408, the present invention is not limited thereto. It can be understood by those of ordinary skill in the art that the conductive pattern 402a may also have more than 2 openings 408 so as to form a reticular conductive pattern (please refer to FIG. 10 and FIG. 11), and accordingly the contacts 406 used for connecting two adjacent conductive patterns 402a also present in a reticular form.

According to the present invention, since a conductive pattern served as an electrode is in circular or reticular form and another conductive pattern is disposed in the corresponding opening to increase the unit area wire length of a particular electrode on the same conductive layer, thus the unit area capacitance of the capacitor can be improved.

In overview, the present invention has at least the following advantages:

1In the capacitor structure of the present invention, the contacts used for connecting two adjacent conductive layers are strip contacts or contacts having the patterns corresponding to the conductive patterns in the conductive layers, thus the unit area capacitance can be improved.

2. In the capacitor structure of the present invention, the boundary of the strip contact or contact having the pattern corresponding to the conductive patterns in the conductive layers is located within the boundary of the conductive pattern in two adjacent conductive layers, thus the bridge effect between various conductive materials in the capacitor can be avoided, and the compatibility of the capacitor is good.

3. By disposing contacts, the capacitor structure in the present invention can be formed by more than 2 conductive layers, thus the unit area capacitance of the capacitor can be further improved.

4. In the capacitor structure of the present invention, two conductive patterns served as electrodes can be disposed correspondingly in various geometric patterns to increase the unit area wire length of a particular electrode on the same conductive layer, thus the unit area capacitance can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A capacitor structure, comprising:
a plurality of conductive layers, which are stacked, each conductive layer having a first conductive pattern and a second conductive pattern;
a dielectric layer, disposed between the first conductive pattern and the second conductive pattern and between two adjacent conductive layers; and
a plurality of contacts, disposed in the dielectric layer, electrically connecting to the first conductive patterns in two adjacent conductive layers and to the second conductive patterns in two adjacent conductive layers respectively, wherein
the contact electrically to connecting the first conductive patterns in two adjacent conductive layers is a first strip contact, which extends between the first conductive patterns in two adjacent conductive layers, and the boundary of the first strip contact is located within the boundary of the first conductive pattern.

2. The capacitor structure as claimed in claim 1, wherein the contact electrically connecting to the second conductive patterns in two adjacent conductive layers includes a second strip contact, which extends between the second conductive patterns in two adjacent conductive layers, and the boundary of the second strip contact is located within the boundary of the second conductive pattern.

3. The capacitor structure as claimed in claim 1, wherein the contact electrically connecting to the second conductive patterns in two adjacent conductive layers includes a column contact.

4. The capacitor structure as claimed in claim 1, wherein the material of the conductive layers includes metal.

5. The capacitor structure as claimed in claim 1, wherein the material of the contacts includes metal.

6. A capacitor structure, comprising:
a plurality of conductive layers, which are stacked, each conductive layer having a first comb conductive pattern and a second comb conductive pattern, the teeth of the first comb conductive pattern and the teeth of the second comb conductive pattern being disposed interlacedly;
a dielectric layer, disposed between the first comb conductive pattern and the second comb conductive pattern and between two adjacent conductive layers; and
a plurality of contacts, disposed in the dielectric layer, electrically connecting to the first comb conductive patterns in two adjacent conductive layers and to the second comb conductive patterns in two adjacent conductive layers respectively, wherein
the contact electrically connecting to the first comb conductive patterns in two adjacent conductive layers is a first comb contact, the pattern of the first comb contact corresponds to the pattern of the first comb conductive pattern, and the boundary of the first comb contact is located within the boundary of the first comb conductive pattern.

7. The capacitor structure as claimed in claim 6, wherein the contact electrically connecting to the second comb conductive patterns in two adjacent conductive layers includes a second comb contact, the pattern of the second comb contact corresponds to the pattern of the second comb conductive pattern, and the boundary of the second comb contact is located within the boundary of the second comb conductive pattern.

8. The capacitor structure as claimed in claim 6, wherein the contact electrically connecting to the second comb conductive patterns in two adjacent conductive layers includes a column contact.

9. The capacitor structure as claimed in claim 6, wherein the material of the conductive layers includes metal.

10. The capacitor structure as claimed in claim 6, wherein the material of the contacts includes metal.

11. A capacitor structure, comprising:
a plurality of conductive layers, which are stacked, each conductive layer having a first spiral conductive pattern and a second spiral conductive pattern disposed interlacedly;
a dielectric layer, disposed between the first spiral conductive pattern and the second spiral conductive pattern and between two adjacent conductive layers; and
a plurality of contacts, disposed in the dielectric layer, electrically connecting to the first spiral conductive patterns in two adjacent conductive layers and to the second spiral conductive patterns in two adjacent conductive layers respectively, wherein
the contact electrically connecting the first spiral conductive patterns in two adjacent conductive layers is a first spiral contact, the pattern of the first spiral contact corresponds to the pattern of the first spiral conductive pattern, and the boundary of the first spiral contact is located within the boundary of the first spiral conductive pattern.

12. The capacitor structure as claimed in claim 11, wherein the contact electrically connecting to the second spiral conductive patterns in two adjacent conductive layers includes a second spiral contact, the pattern of the second spiral contact corresponds to the pattern of the second spiral conductive pattern, and the boundary of the second spiral contact is located within the boundary of the second spiral conductive pattern.

13. The capacitor structure as claimed in claim 11, wherein the contact electrically connecting to the second spiral conductive patterns in two adjacent conductive layers includes a column contact.

14. The capacitor structure as claimed in claim 11, wherein the material of the conductive layers includes metal.

15. The capacitor structure as claimed in claim 11, wherein the material of the contacts includes metal.

16. A capacitor structure, comprising:
a plurality of conductive layers, which are stacked, each conductive layer having a first conductive pattern and a second conductive pattern, the first conductive pattern having an opening, the second conductive pattern being disposed in the opening;
a dielectric layer, disposed between the first conductive pattern and the second conductive pattern and between two adjacent conductive layers; and
a plurality of contacts, disposed in the dielectric layer, electrically connecting to the first conductive patterns in two adjacent conductive layers and to the second conductive patterns in two adjacent conductive layers respectively, wherein
the contact electrically connecting to the first conductive patterns in two adjacent conductive layers is a circular contact, the pattern of the circular contact corresponds to the pattern of the first conductive pattern, and the boundary of the circular contact is located within the boundary of the first conductive pattern.

17. The capacitor structure as claimed in claim 16, wherein the contact electrically connecting to the second conductive patterns in two adjacent conductive layers includes a strip contact, which extends between the second conductive patterns in two adjacent conductive layers, and the boundary of the strip contact is located within the boundary of the second conductive pattern.

18. The capacitor structure as claimed in claim 16, wherein the contact electrically connecting to the second conductive patterns in two adjacent conductive layers includes a column contact.

19. The capacitor structure as claimed in claim 16, wherein the material of the conductive layers includes metal.

20. The capacitor structure as claimed in claim 16, wherein the material of the contacts includes metal.
